(19) United States
(12) Patent Application Publication
(10) Pub. No.: US 2025/0210344 A1
(43) Pub. Date: Jun. 26, 2025

(54) SEMICONDUCTOR DEVICE MANUFACTURING METHOD AND SEMICONDUCTOR DEVICE MANUFACTURING SYSTEM

(71) Applicant: Tokyo Electron Limited, Tokyo (JP)

(72) Inventors: Rio SHIMIZU, Nirasaki City (JP); Tatsuya YAMAGUCHI, Nirasaki City (JP)

(21) Appl. No.: 18/987,382

(22) Filed: Dec. 19, 2024

(30) Foreign Application Priority Data
Dec. 26, 2023 (JP) 2023-218945

(51) Int. Cl. H01L 21/02; C23C 16/04; C23C 16/511

(52) U.S. Cl. CPC H01L 21/02274; C23C 16/045; H01L 21/0234; C23C 16/511

(57) ABSTRACT

A semiconductor device manufacturing method includes: a) embedding a sacrificial material in a recess formed in a substrate; b) covering the recess in which the sacrificial material is embedded with a sealing film; and c) decomposing the sacrificial material in the recess by turning a processing gas into plasma outside the recess and supplying active species contained in the plasma to the sacrificial material via the sealing film, and removing the sacrificial material in the recess via the sealing film.

### CROSS-REFERENCE TO RELATED APPLICATION

This application is based upon and claims the benefit of priority from Japanese Patent Application No. 2023-218945, filed on Dec. 26, 2023, the entire contents of which are incorporated herein by reference.

### TECHNICAL FIELD

Various aspects and embodiments of the present disclosure relate to a semiconductor device manufacturing method and a semiconductor device manufacturing system.

### BACKGROUND

For example, Patent Document 1 below discloses “A semiconductor device manufacturing method, including a first deposition process of depositing a thermally decomposable organic material on a substrate having a recess formed therein, a second deposition process of depositing a silicon nitride film on the organic material, and a desorption process of forming an air gap between the silicon nitride film and the recess by heating the substrate to a predetermined temperature to thermally decompose the organic material and desorbing the organic material below the silicon nitride film via the silicon nitride film, wherein in the second deposition process, the silicon nitride film is deposited by using microwave plasma in a state in which a temperature of the substrate is maintained at 200 degrees C. or lower”.

### PRIOR ART DOCUMENT

### Patent Document

Patent Document 1: Japanese Patent Laid-Open Publication No. 2021-108353

### SUMMARY

Some embodiments of the present disclosure provide a semiconductor device manufacturing method and a semiconductor device manufacturing system, which can reduce residues in an air gap.

According to an aspect of the present disclosure, a semiconductor device manufacturing method includes: a) embedding a sacrificial material in a recess formed in a substrate; b) covering the recess in which the sacrificial material is embedded with a sealing film; and c) decomposing the sacrificial material in the recess by turning a processing gas into plasma outside the recess and supplying active species contained in the plasma to the sacrificial material via the sealing film, and removing the sacrificial material in the recess via the sealing film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a system configuration diagram showing an example of a manufacturing system according to an embodiment of the present disclosure.

FIG. 2 is a diagram showing an example of a film forming apparatus.

FIG. 3 is a diagram showing an example of a plasma processing apparatus.

FIG. 4 is a diagram showing an example of a heating apparatus.

FIG. 5 is a diagram showing an example of a plasma processing apparatus.

FIG. 6 is a flowchart showing an example of a semiconductor device manufacturing method.

FIG. 7 is a diagram showing an example of a process in manufacturing a semiconductor device.

FIG. 8 is a diagram showing an example of a process in manufacturing the semiconductor device.

FIG. 9 is a diagram showing an example of a process in manufacturing the semiconductor device.

FIG. 10 is a diagram showing an example of a process in manufacturing the semiconductor device.

FIG. 11 a diagram showing an example of a process in manufacturing the semiconductor device.

FIG. 12 a diagram showing an example of a process in manufacturing the semiconductor device.

FIG. 13 is a diagram showing an example of a relationship between a heating temperature and an amount of residues.

FIG. 14 is a diagram showing an example of a relationship between a type of plasma and an amount of residues.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a semiconductor device manufacturing method and a semiconductor device manufacturing system disclosed herein will be described in detail with reference to the drawings. The semiconductor device manufacturing method and the semiconductor device manufacturing system disclosed herein are not limited by the following embodiments.

In the technique of Patent Document 1, the air gap is formed in the recess covered with a sealing film by heating the substrate to thermally decompose the organic material embedded in the recess and remove the organic material via a sealing film. However, according to a temperature of heating the substrate, the organic material may not be sufficiently removed and may remain as residues in the recess. When the residues remain in the recess, a volume of the air gap becomes smaller than a desired volume. Further, when amounts of residues differ among a plurality of air gaps, variations in volume among the air gaps occur. Thus, it is desirable to suppress residues in an air gap.

Therefore, the present disclosure provides a technique capable of reducing residues in an air gap.

### [Configuration Example of Manufacturing System 10]

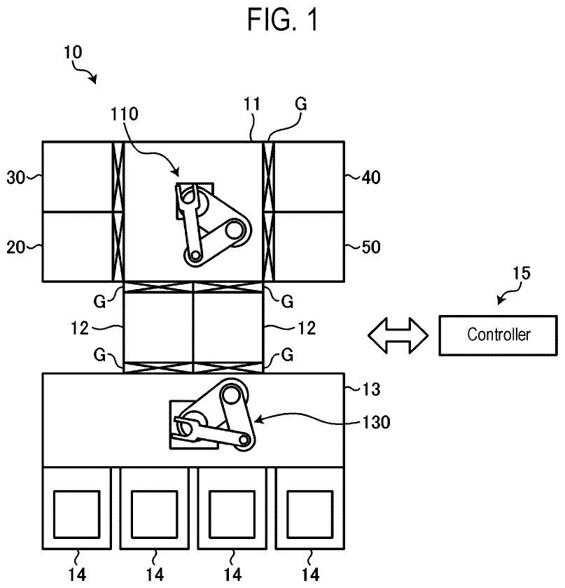

FIG. 1 is a system configuration diagram showing an example of a manufacturing system 10 according to an embodiment of the present disclosure. The manufacturing system 10 includes a vacuum transfer module (VTM) 11, a plurality of load lock modules (LLMs) 12, and an equipment front end module (EFEM) 13. A film forming apparatus 20, a plasma processing apparatus 30, a heating apparatus 40, and a plasma processing apparatus 50 are connected to side walls of the VTM 11 via gate valves G. In addition, although the number of each of the film forming apparatus 20, the plasma processing apparatus 30, the heating apparatus 40, and the plasma processing apparatus 50, which are connected to the VTM 11, is one in the example of FIG. 1, the technique disclosed herein is not limited thereto. As another embodiment, the number of at least one of the film forming apparatus 20, the plasma processing apparatus 30, the heating apparatus 40, or the plasma processing apparatus 50, which are connected to the VTM 11, may be plural.

The film forming apparatus 20 embeds a sacrificial material in a recess formed in a substrate. In the present embodiment, the sacrificial material is a thermally decomposable organic material. The film forming apparatus 20 is an example of a first processing apparatus.

The plasma processing apparatus 30 generates plasma and irradiates the substrate with active species contained in the generated plasma to remove the unnecessary sacrificial material formed on the substrate. Further, the plasma processing apparatus 30 forms a sealing film on the recess in which the sacrificial material is embedded. The plasma processing apparatus 30 is an example of a second processing apparatus.

The heating apparatus 40 heats the substrate in which the sacrificial material is embedded in the recess to thermally decompose the sacrificial material and remove the sacrificial material via the sealing film.

The plasma processing apparatus 50 generates plasma and irradiates an inside of recess of the substrate with active species contained in the generated plasma via the sealing film to remove residues of the sacrificial material remaining in the recess. The plasma processing apparatus 50 is an example of a third processing apparatus.

The LLMs 12 are connected to another side wall of the VTM 11 via gate valves G. Although two LLMs 12 are connected to the VTM 11 in the example of FIG. 1, the number of LLMs 12 connected to the VTM 11 may be more than two or may be one.

A transfer robot 110 is disposed in the VTM 11. The transfer robot 110 transfers the substrate among the film forming apparatus 20, the plasma processing apparatus 30, the heating apparatus 40, the plasma processing apparatus 50, and the LLMs 12. An interior of the VTM 11 is maintained to be an atmosphere of a predetermined pressure, which is lower than atmospheric pressure.

Each of the LLMs 12 has one side wall to which the VTM 11 is connected via a gate valve G, and another side wall to which the EFEM 13 is connected via a gate valve G. When the substrate is loaded from the EFEM 13 into the LLM 12 via the gate valve G, the gate valve G is closed and a pressure inside the LLM 12 is reduced to be substantially the same level as the pressure inside the VTM 11. Then, the gate valve G is opened and the substrate inside the LLM 12 is unloaded into the VTM 11 by the transfer robot 110.

In addition, in a state in which the pressure inside the LLM 12 is substantially the same as the pressure inside the VTM 11, the substrate is loaded, by the transfer robot 110, from the VTM into the LLM 12 via the gate valve G, and the gate valve G is closed. Then, the pressure inside the LLM 12 is increased to be substantially the same level as the pressure inside the EFEM 13. Thereafter, the gate valve G is opened, and the substrate inside the LLM 12 is unloaded into the EFEM 13.

A plurality of load ports 14 is provided on a side wall of the EFEM 13 opposite to the side wall where the gate valves G are provided. A container such as a front opening unified pod (FOUP) capable of accommodating a plurality of substrates is connected to each of the load ports 14. In addition, an aligner module that changes an orientation of the substrate may be provided in the EFEM 13.

The pressure in the EFEM 13 is, for example, atmospheric pressure. A transfer robot 130 is provided in the EFEM 13. The transfer robot 130 transfers the substrate between the LLMs 12 and the containers connected to the load ports 14. A fan filter unit (FFU) or the like is provided at an upper portion of the EFEM 13, so that dry air from which particles have been removed is supplied into the EFEM 13 from above to form a downflow in the EFEM 13. In addition, although the pressure inside the EFEM 13 in the present embodiment is atmospheric pressure, in another embodiment, the pressure inside the EFEM 13 may be controlled to be a positive pressure. With this configuration, it is possible to suppress particles from outside from entering the EFEM 13.

A controller 15 includes a memory, a processor, and an input/output interface. The memory stores a control program and data such as processing recipes. The processor executes the control program read from the memory, and controls respective components of the manufacturing system 10 via the input/output interface based on the recipes stored in the memory.

### [Configuration Example of Film Forming Apparatus 20]

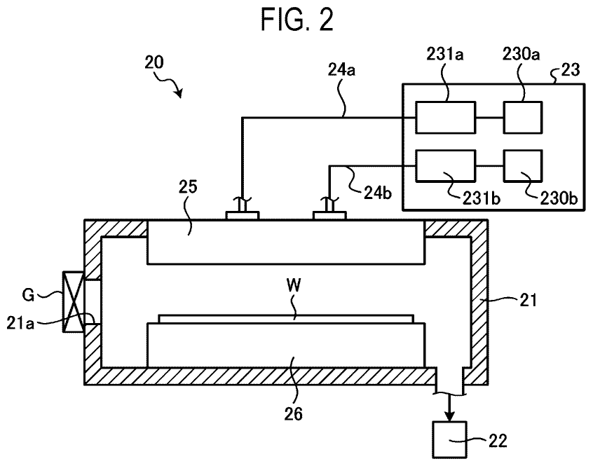

FIG. 2 is a diagram showing an example of the film forming apparatus 20. The film forming apparatus 20 has a chamber 21, an exhaust mechanism 22, a gas supply 23, a shower head 25, and a stage 26. In the present embodiment, the film forming apparatus 20 is, for example, a chemical vapor deposition (CVD) apparatus.

The exhaust mechanism 22 has a vacuum pump that exhausts a gas from an interior of the chamber 21 and a pressure regulating valve that regulates a pressure inside the chamber 21. The interior of the chamber 21 is controlled to a vacuum atmosphere of a predetermined pressure by the exhaust mechanism 22.

The gas supply 23 that supplies plural types of raw material monomers is connected to the chamber 21 via the shower head 25. In the present embodiment, the types of raw material monomers are, for example, isocyanate and amine. Isocyanate is an example of a first monomer, and amine is an example of a second monomer. The gas supply 23 has a raw material source 230a, a raw material source 230b, a vaporizer 231a, and a vaporizer 231b. The raw material source 230a accommodates, for example, liquid isocyanate. The raw material source 230b accommodates, for example, liquid amine.

The vaporizer 231a vaporizes the liquid isocyanate supplied from the raw material source 230a. A vapor of isocyanate vaporized by the vaporizer 231a is introduced into the shower head 25 via a pipe 24a. The vaporizer 231b vaporizes the liquid amine supplied from the raw material source 230b. A vapor of amine vaporized by the vaporizer 231b is introduced into the shower head 25 via a pipe 24b.

The shower head 25 is provided, for example, at an upper portion of the chamber 21, and has a plurality of discharge ports formed in a bottom surface thereof. The shower head 25 discharges the vapor of isocyanate introduced via the pipe 24a and the vapor of amine introduced via the pipe 24b into the chamber 21 in the form of a shower from individual discharge ports.

The stage 26 is provided in the chamber 21. The stage 26 has a temperature control mechanism (not shown). A substrate W loaded into the chamber 21 via an opening 21a formed in a side wall of the chamber 21 is placed on the stage 26. The opening 21a is opened and closed by the gate valve G. The stage 26 has the temperature control mechanism, and a temperature of the substrate W is controlled, by the temperature control mechanism, to be a temperature that is appropriate for vapor deposition polymerization of the raw material monomers supplied from the gas supply 23. The temperature appropriate for the vapor deposition polymerization can be determined according to the types of the raw material monomers. The temperature appropriate for the vapor deposition polymerization is, for example, within a range of 60 degrees C. to 100 degrees C.

By causing a vapor deposition polymerization reaction of two types of raw material monomers on a surface of the substrate W by using the film forming apparatus 20, a polymer organic film is formed on the surface of the substrate W. When the two types of raw material monomers are isocyanate and amine, a polymer organic film having polyurea bonds is formed on the surface of the substrate W. The polymer organic film is an example of a sacrificial material.

### [Configuration Example of Plasma Processing Apparatus 30]

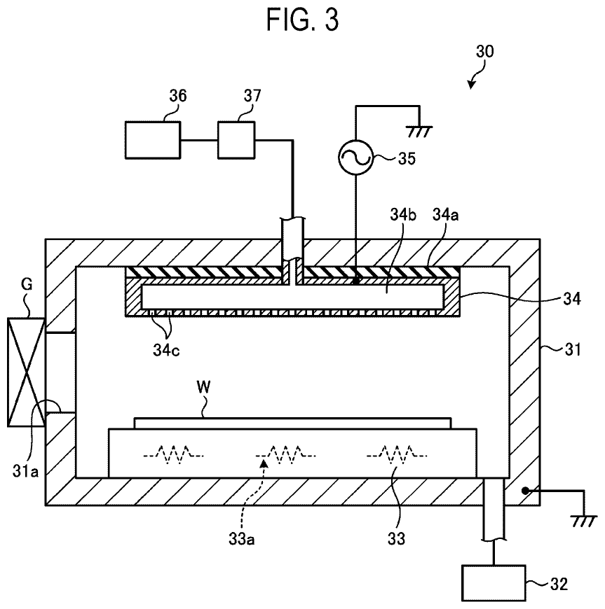

FIG. 3 is a diagram showing an example of the plasma processing apparatus 30. The plasma processing apparatus 30 has a chamber 31 made of a conductive material. The chamber 31 is grounded. An exhaust mechanism 32 is connected to the chamber 31. The exhaust mechanism 32 has a pressure regulating valve. The exhaust mechanism 32 exhausts a gas from an interior of the chamber 31 and controls the pressure regulating valve so that a pressure inside chamber 31 is set to be a predetermined pressure.

A stage 33 on which the substrate W is placed is provided in the chamber 31. The substrate W loaded into the chamber 31 via an opening 31a formed in a side wall of the chamber 31 is placed on the stage 33. The opening 31a is opened and closed by the gate valve G. A heater 33a for heating the substrate W is provided in the stage 33. The stage 33 is electrically connected to a bottom portion of the chamber 31 and functions as an anode electrode. A shower head 34 is provided above the stage 33 to face a top surface of the stage 33. The shower head 34 is made of a conductive material and is supported on an upper portion of the chamber 31 via an insulator 34a. A power supply 35 for supplying radio-frequency power for plasma generation is connected to the shower head 34. The shower head 34 functions as a cathode electrode with respect to the stage 33.

A gas source 36 supplies a processing gas. A flow rate controller 37 adjusts a flow rate of the processing gas supplied from the gas source 36 and supplies the processing gas into a diffusion space 34b of the shower head 34. The processing gas supplied into the diffusion space 34b diffuses in the diffusion space 34b, and is supplied in the form of a shower into the chamber 31 from a plurality of discharge ports 34c formed in a bottom surface of the diffusion space 34b. Although the single gas source 36 and the single flow rate controller 37 are shown in the example of FIG. 3, actually, a set of the gas source 36 and the flow rate controller 37 is provided for each type of gases used.

The processing gas supplied into the chamber 31 via the shower head 34 is turned into plasma by the radio-frequency power supplied from the power supply 35 into the chamber 31. Thus, a part of the sacrificial material formed on the substrate W is removed by ions or active species contained in the plasma, or a sealing film is formed on the substrate W. In the present embodiment, the sealing film is, for example, a silicon oxide film. Alternatively, in another example, the sealing film may be another silicon-containing film such as a silicon nitride film.

### [Configuration Example of Heating Apparatus 40]

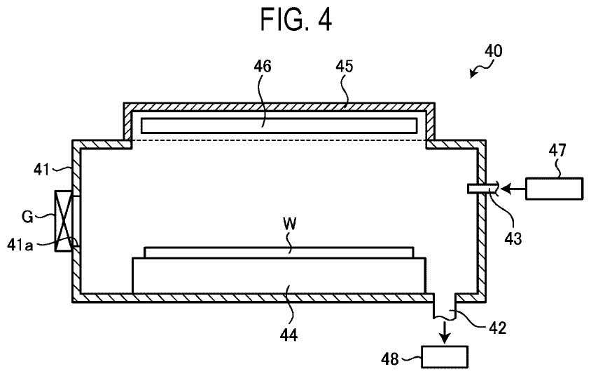

FIG. 4 is a diagram showing an example of the heating apparatus 40. The heating apparatus 40 has a chamber 41, an exhaust pipe 42, a supply pipe 43, a stage 44, a lamp house 45, and a lamp 46.

The stage 44 on which the substrate W is placed is provided in the chamber 41. The lamp house 45 is provided at a position facing a surface of the stage 44 on which the substrate W is placed. The lamp 46 such as an infrared lamp is disposed in the lamp house 45.

A gas supply 47 is connected to a side wall of the chamber 41 via the supply pipe 43. The gas supply 47 supplies an inert gas, such as N₂ gas, into the chamber 41 via the supply pipe 43. An opening 41a for loading and unloading the substrate W is formed in the side wall of the chamber 41. The opening 41a is opened and closed by the gate valve G.

An exhaust device 48 is connected to a bottom portion of the chamber 41 via the exhaust pipe 42. The exhaust device 48 has a pressure regulating valve. The exhaust device 48 exhausts a gas from an interior of the chamber 41 and controls the pressure regulating valve so that a pressure inside the chamber 41 is set to be a predetermined pressure.

In a state in which the substrate W is placed on the stage 44 and the inert gas is supplied into the chamber 41 via the supply pipe 43, by turning the lamp 46 on, the substrate W can be heated to a predetermined temperature in an inert gas atmosphere. In the present embodiment, the substrate W is heated to a temperature of, for example, 400 degrees C. or less.

### [Configuration Example of Plasma Processing Apparatus 50]

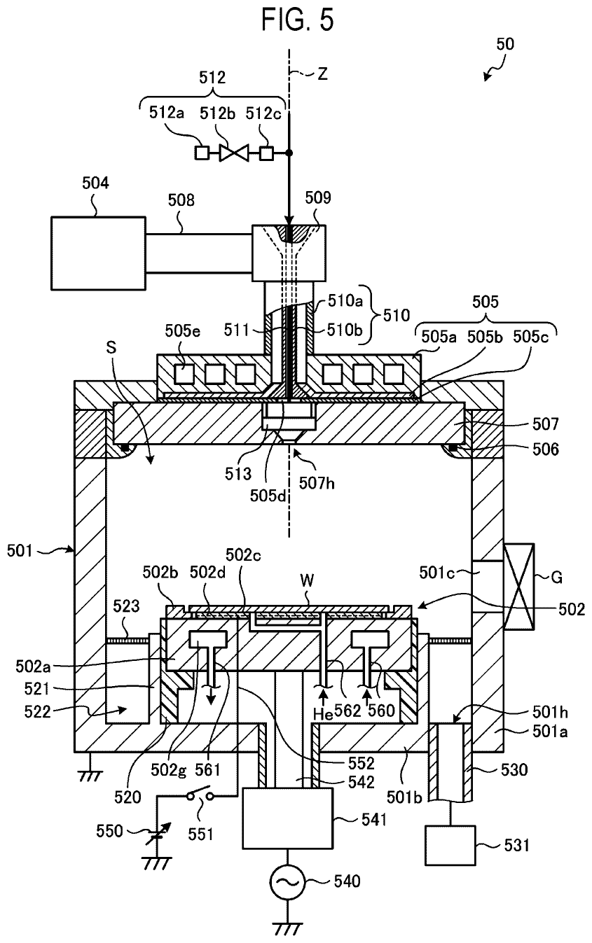

FIG. 5 is a diagram showing an example of the plasma processing apparatus 50. The plasma processing apparatus 50 includes a chamber 501 and a microwave output device 504.

The chamber 501 is made of, for example, aluminum having an anodized surface and is formed in a substantially cylindrical shape. The chamber 501 provides a substantially cylindrical processing space S formed therein. The chamber 501 is securely grounded. The chamber 501 has a sidewall 501a and a bottom wall 501b. A central axis of the sidewall 501a is defined as a Z-axis. The bottom wall 501b is provided on a lower end of the sidewall 501a. An exhaust port 501h for exhaust is provided in the bottom wall 501b. An opening 501c for loading and unloading the substrate W is formed in the sidewall 501a. The opening 501c is opened and closed by the gate valve G. An upper end of the sidewall 501a is open.

A dielectric window 507 is provided at an upper end portion of the sidewall 501a. An opening of the upper end portion of the sidewall 501a is closed from above by the dielectric window 507. A bottom surface of the dielectric window 507 faces the processing space S. An O-ring 506 is disposed between the dielectric window 507 and the upper end portion of the sidewall 501a.

A stage 502 is provided in the chamber 501. The stage 502 is provided to face the dielectric window 507 in a Z-axis direction. A space between the stage 502 and the dielectric window 507 is the processing space S. The substrate W is placed on the stage 502.

The stage 502 has a base 502a and an electrostatic chuck 502c. The base 502a is formed of, for example, a conductive material, such as aluminum, and has a substantially disk shape. The base 502a is disposed in the chamber 501 so that a central axis of the base 502a substantially coincides with the Z-axis.

The base 502a is supported by a tubular support 520 that is made of an insulating material and extends in a direction along the Z-axis. A conductive tubular support 521 is provided on an outer periphery of the tubular support 520. The tubular support 521 extends from the bottom wall 501b of the chamber 501 toward the dielectric window 507 along the outer periphery of the tubular support 520. An annular exhaust path 522 is formed between the tubular support 521 and the sidewall 501a.

An annular baffle plate 523 having a plurality of through-holes formed in a thickness direction is provided at an upper portion of the exhaust path 522. The exhaust port 501h described above is provided below the baffle plate 523. An exhaust device 531 having a vacuum pump, such as a turbomolecular pump, or an automatic pressure regulating valve is connected to the exhaust port 501h via an exhaust pipe 530. The exhaust device 531 is capable of depressurizing the processing space S to a predetermined vacuum level.

The base 502a also functions as a radio-frequency electrode. A radio-frequency (RF) power supply 540 that outputs an RF signal for RF bias is electrically connected to the base 502a via a power feeding rod 542 and a matching unit 541. The RF power supply 540 supplies bias power of a predetermined frequency (e.g., 13.56 MHz), which is appropriate for controlling energy of ions introduced into the substrate W, to the base 502a via the matching unit 541 and the power feeding rod 542.

The matching unit 541 includes a matcher for matching an impedance on a side of the RF power supply 540 with an impedance on a side of a load such as an electrode, plasma, and the chamber 501. A blocking capacitor for generating self-bias is included in the matcher.

An electrostatic chuck 502c is provided on a top surface of the base 502a. The electrostatic chuck 502c adsorbs and holds the substrate W by electrostatic force. The electrostatic chuck 502c has a substantially disk-shaped exterior, and a heater 502d is embedded in the electrostatic chuck 502c. A heater power supply 550 is electrically connected to the heater 502d via a wire 552 and a switch 551. The heater 502d heats the substrate W placed on the electrostatic chuck 502c by power supplied from the heater power supply 550. An edge ring 502b is provided on the base 502a. The edge ring 502b is disposed to surround the substrate W and the electrostatic chuck 502c. The edge ring 502b is also called a focus ring.

A flow path 502g is provided inside the base 502a. A coolant is supplied to the flow path 502g from a chiller unit (not shown) via a pipe 560. The coolant supplied to the flow path 502g is returned to the chiller unit via a pipe 561. As the coolant having a temperature controlled by the chiller unit circulates in the flow path 502g of the base 502a, a temperature of the base 502a is controlled. The temperature of the substrate W placed on the electrostatic chuck 502c is controlled by the coolant flowing in the base 502a and by the heater 502d disposed inside the electrostatic chuck 502c.

In addition, a pipe 562 for supplying a heat transfer gas, such as helium gas, between the electrostatic chuck 502c and the substrate W is provided in the stage 502.

The microwave output device 504 outputs microwaves for exciting the processing gas supplied into the chamber 501. The microwave output device 504 generates microwaves having a frequency of, for example, 2.4 GHz.

An output portion of the microwave output device 504 is connected to one end of a waveguide 508. The other end of the waveguide 508 is connected to a mode converter 509. The mode converter 509 converts a mode of the microwaves output from the waveguide 508 and supplies the mode-converted microwaves to an antenna 505 via a coaxial waveguide 510.

The coaxial waveguide 510 includes an outer conductor 510a and an inner conductor 510b. The outer conductor 510a and the inner conductor 510b have a substantially cylindrical shape and are disposed above the antenna 505 so that central axes of the outer conductor 510a and the inner conductor 510b substantially coincide with the Z-axis.

The antenna 505 includes a cooling jacket 505a, a dielectric plate 505b, and a slot plate 505c. The slot plate 505c is formed of a conductive metal and has a substantially disk shape. The slot plate 505c is provided on a top surface of the dielectric window 507 so that a central axis of the slot plate 505c coincides with the Z-axis. A plurality of slot holes is formed in the slot plate 505c. The slot holes are arranged around the central axis of the slot plate 505c, while evert two of the slot holes form a pair.

The dielectric plate 505b is formed of a dielectric material, such as quartz, and has a substantially disk shape. The dielectric plate 505b is disposed on the slot plate 505c so that a central axis of the dielectric plate 505b substantially coincides with the Z-axis. The cooling jacket 505a is provided on the dielectric plate 505b.

The cooling jacket 505a is formed of a material having a conductive surface, and has a flow path 505e formed in the cooling jacket 505a. A coolant is supplied into the flow path 505e from a chiller unit (not shown). A lower end of the outer conductor 510a is electrically connected to an upper surface of the cooling jacket 505a. In addition, a lower end of the inner conductor 510b is electrically connected to the slot plate 505c via an opening formed in central portions of the cooling jacket 505a and the dielectric plate 505b.

The microwaves propagating in the coaxial waveguide 510 propagate in the dielectric plate 505b, and propagate from the slot holes of the slot plate 505c to the dielectric window 507. The microwaves propagating to the dielectric window 507 are radiated into the processing space S from a bottom surface of the dielectric window 507.

A gas pipe 511 is provided on an inner side of the inner conductor 510b of the coaxial waveguide 510. A through-hole 505d through which the gas pipe 511 can pass is formed in a central portion of the slot plate 505c. The gas pipe 511 extends in the inner side of the inner conductor 510b and is connected to a gas supply 512.

The gas supply 512 supplies the processing gas for processing the substrate W to the gas pipe 511. The gas supply 512 includes a gas source 512a, a valve 512b, and a flow rate controller 512c. The gas source 512a is a supply source of the processing gas. The valve 512b controls supply of the processing gas from the gas source 512a and stop the supply of the processing gas. The flow rate controller 512c is, for example, a mass flow controller and controls a flow rate of the processing gas from the gas source 512a.

An injector 513 is provided in the dielectric window 507. The injector 513 injects the processing gas, which is supplied via the gas pipe 511, into the processing space S via a through-hole 507h formed in the dielectric window 507. The processing gas injected into the processing space S is excited by the microwaves radiated into the processing space S via the dielectric window 507. Thus, the processing gas is turned into plasma in the processing space S, and ions, radicals, and the like contained in the plasma are radiated to the substrate W. Therefore, it is possible to remove residues remaining in the recess of the substrate W after the substrate W is heated.

### [Semiconductor Device Manufacturing Method]

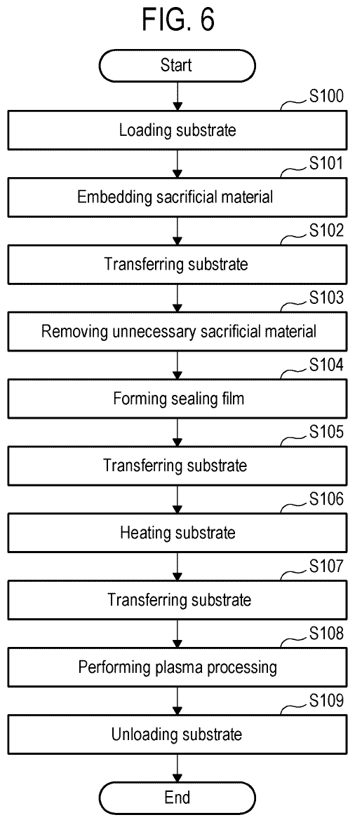

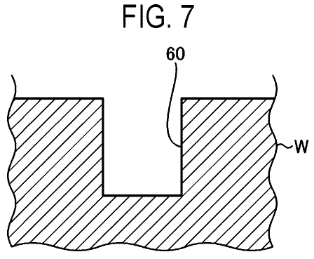

FIG. 6 is a flowchart showing an example of a semiconductor device manufacturing method. The manufacturing method shown in FIG. 6 is implemented by controlling respective components of the manufacturing system 10 by the controller 15. The example of the semiconductor device manufacturing method will be described below with reference to FIGS. 7 to 12.

First, the substrate W is loaded into the chamber 21 of the film forming apparatus 20 (step S100). In step S100, the substrate W having a recess 60 formed therein is loaded into the chamber 21 of the film forming apparatus 20 as shown in, for example, FIG. 7.

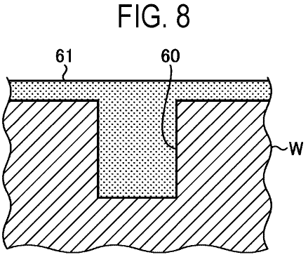

Next, a sacrificial material is embedded in the recess 60 (step S101). Step S101 is an example of Process a). In step S101, a first monomer and a second monomer are supplied into the chamber 21 and cause a deposition polymerization reaction of the first monomer and the second monomer, thereby embedding the sacrificial material in the recess 600 of the substrate W. In the present embodiment, the first monomer is, for example, isocyanate, the second monomer is, for example, amine, and the sacrificial material has polyurea bonds. Thus, a sacrificial material 61 is embedded in the recess 60 as shown in, for example, FIG. 8.

In step S101, the sacrificial material 61 is embedded in the recess of the substrate W under, for example, the following processing conditions.

Pressure in the chamber 21: 0.5 to 20 Torr (66.7 to 2666 Pa)
Flow rate of isocyanate vapor: 1 to 20 sccm (0.0017 to 0.034 Pa·m³/s)
Flow rate of amine vapor: 1 to 20 sccm (0.0017 to 0.034 Pa·m³/s)
Temperature of the substrate W: 40 to 150 degrees C.

Next, the substrate W is transferred from the film forming apparatus 20 to the plasma processing apparatus 30 (step S102). In step S102, the substrate W is unloaded from the chamber 21 of the film forming apparatus 20 by the transfer robot 110 in the VTM 11 and is loaded into the chamber 31 of the plasma processing apparatus 30.

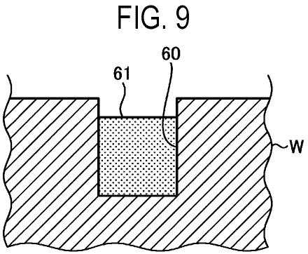

Next, the unnecessary sacrificial material 61 on the substrate W is removed (step S103). In step S103, plasma is generated from the processing gas in the chamber 31. The processing gas is, for example, a gas mixture of hydrogen gas and nitrogen gas. Then, the unnecessary sacrificial material 61 formed around the recess 60 is removed by the generated plasma as shown in, for example, FIG. 9. In step S103, the unnecessary sacrificial material 61 is removed by the plasma processing apparatus 30 under, for example, the following processing conditions.

Pressure in the chamber 31: 0.05 to 1.0 Torr (6.67 to 133 Pa)
Processing gas: H₂/N₂=100 to 300 sccm/100 to 300 sccm
   (0.17 to 0.51 Pa·m³/s/0.17 to 0.51 Pa·m³/s)
Radio-frequency power: 100 to 400 W
Temperature of the substrate W: 40 to 200 degrees C.

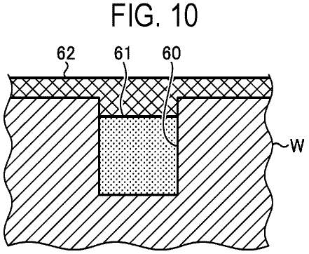

Next, a sealing film is formed on the recess 60 in which the sacrificial material 61 is embedded (step S104). Step S104 is an example of Process b). In step S104, plasma is generated from a processing gas, such as organic aminosilane, in the chamber 31. Then, a sealing film 62 is formed on the recess 60 in which the sacrificial material 61 is embedded by the generated plasma as shown in, for example, FIG. 10. In the present embodiment, the sealing film 62 is, for example, a silicon oxide film. The sealing film 62 may be, for example, another silicon-containing film such as a silicon nitride film. In step S104, the sealing film 62 is formed by the plasma processing apparatus 30 under, for example, the following processing conditions.

Pressure in the chamber 31: 0.1 to 10 Torr (13.3 to 1333 Pa)
Processing gas: organic aminosilane=10 to 50 sccm (0.017 to 0.085 Pa·m³/s)
Radio-frequency power: 50 to 200 W
Temperature of the substrate W: 20 to 200 degrees C.

Next, the substrate W is transferred from the plasma processing apparatus 30 to the heating apparatus 40 (step S105). In step S105, the substrate W is unloaded from the chamber 31 of the plasma processing apparatus 30 by the transfer robot 110 in the VTM 11 and is loaded into the chamber 41 of the heating apparatus 40.

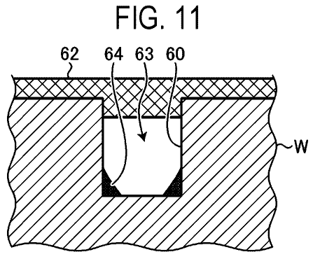

Next, the substrate W is heated (step S106). Step S106 is an example of Process d). In step S106, the sacrificial material 61 is thermally decomposed by heating the substrate W to a temperature of, for example, 400 degrees C. or less, and the sacrificial material 61 is desorbed via the sealing film 62. As a result, an air gap 63 is formed between the sealing film 62 and the recess 60 as shown in, for example, FIG. 11. In step S106, the substrate W is heated under, for example, the following processing conditions.

Pressure in the chamber 41: 0.5 to 20 Torr (66.7 to 2666 Pa)
Gas supplied into the chamber 41: N₂=200 to 2000 sccm (0.34 to 3.4 Pa·m³/s)
Temperature of the substrate W: 350 to 400 degrees C.

Next, the substrate W is transferred from the heating apparatus 40 to the plasma processing apparatus 50 (step S107). In step S107, the substrate W is unloaded from the chamber 41 of the heating apparatus 40 by the transfer robot 110 in the VTM 11 and is loaded into the chamber 501 of the plasma processing apparatus 50.

Next, plasma processing is performed (step S108). Step S108 is an example of Process c). In step S108, plasma is generated from a processing gas in the chamber 501. In the present embodiment, the processing gas is, for example, oxygen gas. As another example, the processing gas may be a noble gas such as argon gas or may be hydrogen gas or nitrogen gas.

In step S108, the processing gas is turned into plasma outside the recess 60. Then, active species or ions contained in the plasma are supplied into the recess 60 via the sealing film 62. In step S108, plasma processing is performed by the plasma processing apparatus 50 under, for example, the following processing conditions.

Pressure in the chamber 501: 0.5 to 1 Torr (66.7 to 133 Pa)
Processing gas: H₂=10 to 50 sccm (0.017 to 0.085 Pa·m³/s)
Power of the microwaves: 100 to 200 W
Temperature of the substrate W: 20 to 400 degrees C.

Next, the substrate W is unloaded from the plasma processing apparatus 50 (step S109). Then, the semiconductor device manufacturing method shown in the flowchart is completed.

Here, according to a heat-resistance temperature of the substrate W or other structures formed on the substrate W, the substrate W may not be heated to a high temperature or may not be heated for a long time. In such a case, after removing the sacrificial material 61 by heating the substrate W, residues 64 may remain in the recess 60 as shown in, for example, FIG. 11. When the residues 64 remain in the recess 60, a volume of the air gap 63 may be smaller than a desired volume. Further, when an amount of the residues 64 differs among a plurality of air gaps 63, volume variation occurs among the air gaps 63.

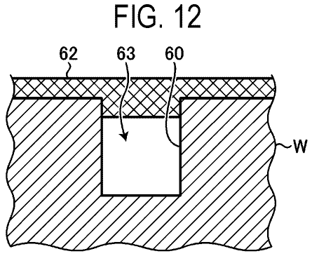

Therefore, in the present embodiment, after removing the sacrificial material 61 by heating the substrate W, in step S108, the processing gas is turned into plasma outside the recess 60, and active species or ions contained in the plasma are supplied into the recess 60 via the sealing film 62. The residues 64 remaining in the recess 60 are decomposed by the active species or ions supplied into the recess 60, and are desorbed via the sealing film 62. As a result, the residues 64 in the recess 60 can be reduced as shown in, for example, FIG. 12. Accordingly, the volume of the air gap 63 can be made closer to a desired volume, and volume variation among the plurality of air gaps 63 can be reduced.

### [Relationship Between Heating Temperature and Residues]

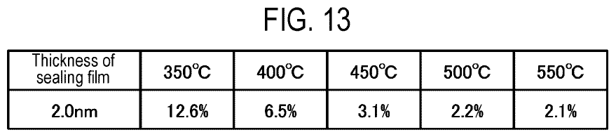

FIG. 13 is a diagram showing an example of a relationship between a heating temperature and an amount of residues. In the example of FIG. 13, a ratio of an amount of the residues 64 after heating to an amount of the sacrificial material 61 before heating is shown. In the example of FIG. 13, a thickness of the sealing film 62 is 2.0 nm.

For example, as shown in FIG. 13, when the heating temperature of the substrate W is increased, the amount of the residues 64 can be reduced. However, when the heating temperature cannot be increased to be so high, the amount of the residues increases. For example, when the heating temperature is 400 degrees C., about 6.5% of the sacrificial material 61 remains in the recess 60 as the residues 64.

[Relationship between Plasma Type and Residues]

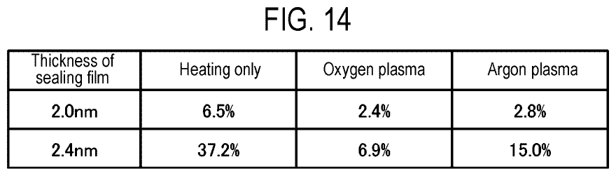

FIG. 14 is a diagram showing an example of a relationship between a plasma type and an amount of residues. In the example of FIG. 14, a ratio of an amount of the residues 64 to an amount of the sacrificial material 61 before heating is shown.

In a case of the sealing film 62 having a thickness of 2.0 nm, when the sacrificial material 61 was removed only by heating of 400 degrees C., about 6.5% of the sacrificial material 61 remained in the recess 60 as the residues 64. On the other hand, when oxygen gas was turned into plasma (oxygen plasma) after the heating of 400 degrees C., then the amount of the residues 64 was reduced to about 2.4%. In addition, when argon gas was turned into plasma (argon plasma) after the heating of 400 degrees C., the amount of the residues 64 was reduced to about 2.8%.

In addition, in a case of the sealing film 62 having a thickness of 2.4 nm, when the sacrificial material 61 was removed only by heating of 400 degrees C., about 37.2% of the sacrificial material 61 remained in the recess 60 as the residue 64. On the other hand, when oxygen gas was turned into plasma (oxygen plasma) after the heating of 400 degrees C., the amount of the residues 64 was reduced to about 6.9%. In addition, when argon gas was turned into plasma (argon plasma) after the heating of 400 degrees C., the amount of the residues 64 was reduced to about 15.0%.

As is obvious from the results shown in FIG. 14, by generating plasma of oxygen gas or argon gas after heating and supplying active species or the like contained in the plasma into the recess 60 via the sealing film 62, the residues 64 can be reduced as compared with the cases of heating only. In addition, in terms of a reduction rate of the residues 64, the reduction rate of the residues 64 is greater when oxygen gas is turned into plasma than when argon gas is formed into plasma. Although argon gas was turned into plasma in the example of FIG. 14, it is considered that the same effect can be obtained even when a noble gas other than argon gas is used.

The present embodiment has been described hereinabove. As described above, the semiconductor device manufacturing method according to the present embodiment includes Processes a), b), and c). In Process a), a sacrificial material (the sacrificial material 61) is embedded in a recess (the recess 60) formed in a substrate (the substrate W). In Process b), the recess in which the sacrificial material is embedded is covered with a sealing film (the sealing film 62). In Process c), the sacrificial material in the recess is decomposed by turning a processing gas into plasma outside the recess and supplying active species contained in the plasma to the sacrificial material via the sealing film, and the sacrificial material in the recess is removed via the sealing film. Thus, residues in an air gap can be reduced.

In the above-described embodiment, the sacrificial material is a thermally decomposable organic material. The semiconductor device manufacturing method according to the above-described embodiment further includes Process d). Process d) is a process performed between Process b) and Process c), in which at least a part of the sacrificial material in the recess is removed via the sealing film by heating the substrate to a temperature at which the sacrificial material is thermally decomposed. Thus, the sacrificial material can be removed efficiently.

In the above-described embodiment, the sacrificial material is a thermally decomposable organic material and contains urea bonds. In Process a), gases of a first monomer and a second monomer are supplied into a chamber into which the substrate has been loaded, and the sacrificial material is embedded in the recess by vapor deposition polymerization of the first monomer and the second monomer. In addition, the first monomer is isocyanate, and the second monomer is amine. Thus, since the sacrificial material can be decomposed by heating, the sacrificial material can be removed efficiently.

In the above-described embodiment, the heating temperature of the substrate is 400 degrees C. or less. Thus, it is possible to suppress thermal damage on the substrate W or other structures formed on the substrate W.

In the above-described embodiment, the processing gas used in Process c) includes at least one of hydrogen gas, nitrogen gas, oxygen gas, or a noble gas. Thus, it is possible to reduce residues in the air gap.

In the above-described embodiment, the sealing film is a silicon oxide film or a silicon nitride film. Thus, it is possible to efficiently remove the sacrificial material in the recess.

In the above-described embodiment, in Process c), the processing gas is turned into plasma by microwaves. Thus, it is possible to turn the processing gas into plasma efficiently.

In addition, a semiconductor device manufacturing system (the manufacturing system 10) according to the above-described embodiment includes a first processing apparatus (the film forming apparatus 20), a second processing apparatus (the plasma processing apparatus 30), a third processing apparatus (the plasma processing apparatus 50), and a controller (the controller 15) that controls the first processing apparatus, the second processing apparatus, and the third processing apparatus. The controller executes Process a), Process b), and Process c). In Process a), a sacrificial material is embedded in a recess by using the first processing apparatus. In Process b), the recess in which the sacrificial material is embedded is covered with a sealing film by using the second processing apparatus. In Process c), by using the third processing apparatus, the sacrificial material in the recess is decomposed by turning a processing gas into plasma outside the recess and supplying active species contained in the plasma to the sacrificial material via the sealing film, and the sacrificial material in the recess is removed via the sealing film. Thus, the residues in the air gap can be reduced.

### [Others]

The technique disclosed in the present application is not limited to the above-described embodiment, and various modifications can be made within the scope of the present disclosure.

For example, in the above-described embodiment, the substrate W is heated after the sealing film 62 is formed on the recess 60 in which the sacrificial material 61 is embedded, and the substrate W is irradiated with plasma after the sacrificial material 61 in the recess 60 is removed to a certain extent. However, the technique disclosed herein is not limited thereto. For example, as another embodiment, the substrate W may be irradiated with plasma without heating the substrate W after the sealing film 62 is formed on the recess 60 in which the sacrificial material 61 is embedded. With this configuration, the heating apparatus 40 is not necessary, and the manufacturing system 10 can be made smaller in size.

Further, in the above-described embodiment, the substrate W is heated after the sealing film 62 is formed on the recess 60 in which the sacrificial material 61 is embedded, and the substrate W is irradiated with plasma after the sacrificial material 61 in the recess 60 is removed to a certain extent, but the technique disclosed herein is not limited thereto. For example, as another embodiment, after the sealing film 62 is formed on the recess 60 in which the sacrificial material 61 is embedded, the substrate W may be irradiated with plasma while being heated to a temperature of 400 degrees C. or less. In this case, the irradiation of the substrate W with the plasma is performed by the plasma processing apparatus 50, and the substrate W is heated by, for example, the heater 502d embedded in the electrostatic chuck 502c of the plasma processing apparatus 50. With this configuration, the sacrificial material 61 in the recess 60 can be removed in a shorter time. In addition, since the heating apparatus 40 is not necessary, the manufacturing system 10 can be made smaller in size.

In the above-described embodiment, the substrate W may be heated after the sealing film 62 is formed on the recess 60 in which the sacrificial material 61 is embedded, and may also be heated to a temperature of 400 degrees C. or less when the substrate W is irradiated with the plasma.

In the above-described embodiment, in order to remove the residues 64, oxygen gas is turned into plasma and active species or ions contained in the plasma are supplied into the recess 60 via the sealing film 62, but the technique disclosed herein is not limited thereto. For example, in a case where an air gap is formed between metal wires, when the residues in the recess between the metal wires are removed by plasma using oxygen gas, the metal wires may be oxidized by active species or ions derived from oxygen to increase resistance values of the metal wires. Therefore, in the case where the air gap is formed between the metal wires, a gas that does not contain oxygen, such as hydrogen gas, nitrogen gas, and a noble gas, may be turned into plasma. With this configuration, it is possible to remove the residues remaining in the air gap between the metal wires while suppressing an increase in the resistance values of the metal wires.

In the above-described embodiment, a thermally decomposable organic material is used as the sacrificial material 61, but the technique disclosed herein is not limited thereto. For example, as another embodiment, a silicon-containing material, such as non-crystalline silicon, or a carbon-containing material, such as amorphous carbon, may be used as the sacrificial material 61. When such a material is used as the sacrificial material 61, the heating apparatus 40 is not necessary, and step S106 is also not necessary. When the silicon-containing material is used as the sacrificial material 61, an oxygen-containing gas, for example, is used as the processing gas in the plasma processing of step S108. When the carbon-containing material is used as the sacrificial material 61, oxygen gas, for example, is used as the processing gas in the plasma processing of step S108.

In the above-described embodiment, capacitively coupled plasma is used as a plasma source in steps S103 and S104 and microwave plasma is used as the plasma source in step S108, but the technique disclosed herein is not limited thereto. As another embodiment, microwave plasma may be used as the plasma source in steps S103 and S104. In addition, capacitively coupled plasma may be used as the plasma source in step S108. Alternatively, in steps S103, S104, and S108, other plasma sources such as inductively coupled plasma or magnetron plasma may be used as the plasma source.

In the above-described embodiment, the sacrificial material 61, which is a thermally decomposable polymer having urea bonds (—NH—CO—NH—), is formed on the surface of the substrate W by using isocyanate as the first monomer and amine as the second monomer, but the technique disclosed herein is not limited thereto. For example, the sacrificial material 61, which is a thermally decomposable polymer having 2-aminoethanol bonds (—NH—CH₂—CH(OH)—), may be formed on the surface of the substrate W by using epoxide as the first monomer and amine as the second monomer. Alternatively, the sacrificial material 61, which is a thermally decomposable polymer having urethane bonds (—NH—CO—O—), may be formed on the surface of the substrate W by using isocyanate as the first monomer and alcohol as the second monomer. Alternatively, the sacrificial material 61, which is a thermally decomposable polymer having amide bonds (—NH—CO—), may be formed on the surface of the substrate W by using halogenated acyl as the first monomer and amine as the second monomer. Alternatively, the sacrificial material 61, which is a thermally decomposable polymer having imide bonds (—CO—N(−)—CO—), may be formed on the surface of the substrate W by using carboxylic acid anhydride as the first monomer and amine as the second monomer.

It should be understood that the embodiment disclosed herein is exemplary in all aspects and is not restrictive. Indeed, the embodiment described above can be implemented in various forms. Further, the above-described embodiment may be omitted, replaced, or modified in various forms without departing from the scope and spirit of the appended claims.

In addition, regarding the above-described embodiment, the following supplementary notes are disclosed.

### (Supplementary Note 1)

A semiconductor device manufacturing method, including:
a) embedding a sacrificial material in a recess formed in a substrate;
b) covering the recess in which the sacrificial material is embedded with a sealing film; and
c) decomposing the sacrificial material in the recess by turning a processing gas into plasma outside the recess and supplying active species contained in the plasma to the sacrificial material via the sealing film, and removing the sacrificial material in the recess via the sealing film.

### (Supplementary Note 2)

The semiconductor device manufacturing method of Supplementary Note 1, wherein the sacrificial material is a thermally decomposable organic material, and
wherein the semiconductor device manufacturing method further includes, between b) and c), d) removing at least a part of the sacrificial material in the recess via the sealing film by heating the substrate to a temperature at which the sacrificial material is thermally decomposed.

### (Supplementary Note 3)

The semiconductor device manufacturing method of Supplementary Note 1 or 2, wherein the sacrificial material is a thermally decomposable organic material, and
wherein in c), the substrate is heated to the temperature at which the sacrificial material is thermally decomposed.

### (Supplementary Note 4)

The semiconductor device manufacturing method of Supplementary Note 2 or 3, wherein the sacrificial material is a thermally decomposable organic material,
wherein in a), gases of a first monomer and a second monomer are supplied into a chamber into which the substrate has been loaded, and the sacrificial material is embedded in the recess by vapor deposition polymerization of the first monomer and the second monomer,
wherein the first monomer is isocyanate,
wherein the second monomer is amine, and
wherein the sacrificial material contains urea bonds.

### (Supplementary Note 5)

The semiconductor device manufacturing method of any one of Supplementary Notes 2 to 4, wherein the temperature to which the substrate is heated is 400 degrees C. or less.

### (Supplementary Note 6)

The semiconductor device manufacturing method of any one of Supplementary Notes 1 to 5, wherein the processing gas includes at least one of hydrogen gas, nitrogen gas, oxygen gas, or a noble gas.

### (Supplementary Note 7)

The semiconductor device manufacturing method of Supplementary Note 6, wherein the processing gas includes at least one of the hydrogen gas, the nitrogen gas, or the noble gas.

### (Supplementary Note 8)

The semiconductor device manufacturing method of any one of Supplementary Notes 1 to 7, wherein the sealing film is a silicon oxide film or a silicon nitride film.

### (Supplementary Note 9)

In the semiconductor device manufacturing method of any one of Supplementary Notes 1 to 9, wherein in c), the processing gas is turned into the plasma by microwaves.

### (Supplementary Note 10)

A semiconductor device manufacturing system, including:
a first processing apparatus;
a second processing apparatus;
a third processing apparatus; and
a controller configured to control the first processing apparatus, the second processing apparatus, and the third processing apparatus,
wherein the controller executes:
a) by using the first processing apparatus, embedding a sacrificial material in a recess;
b) by using the second processing apparatus, covering the recess in which the sacrificial material is embedded with a sealing film; and
c) by using the third processing apparatus, decomposing the sacrificial material in the recess by turning a processing gas into plasma outside the recess and supplying active species contained in the plasma to the sacrificial material via the sealing film, and removing the sacrificial material in the recess via the sealing film.

According to various aspects and embodiments of the present disclosure, it is possible to reduce residues in an air gap.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device manufacturing method, comprising:
a) embedding a sacrificial material in a recess formed in a substrate;
b) covering the recess in which the sacrificial material is embedded with a sealing film; and
c) decomposing the sacrificial material in the recess by turning a processing gas into plasma outside the recess and supplying active species contained in the plasma to the sacrificial material via the sealing film, and removing the sacrificial material in the recess via the sealing film.

2. The semiconductor device manufacturing method of claim 1, wherein the sacrificial material is a thermally decomposable organic material, and
wherein the semiconductor device manufacturing method further comprises, between b) and c), d) removing at least a part of the sacrificial material in the recess via the sealing film by heating the substrate to a temperature at which the sacrificial material is thermally decomposed.

3. The semiconductor device manufacturing method of claim 2, wherein in c), the substrate is heated to the temperature at which the sacrificial material is thermally decomposed.

4. The semiconductor device manufacturing method of claim 2,
wherein in a), gases of a first monomer and a second monomer are supplied into a chamber into which the substrate has been loaded, and the sacrificial material is embedded in the recess by vapor deposition polymerization of the first monomer and the second monomer,
wherein the first monomer is isocyanate,
wherein the second monomer is amine, and
wherein the sacrificial material contains urea bonds.

5. The semiconductor device manufacturing method of claim 2, wherein the temperature to which the substrate is heated is 400 degrees C. or less.

6. The semiconductor device manufacturing method of claim 1, wherein the processing gas includes at least one of hydrogen gas, nitrogen gas, oxygen gas, or a noble gas.

7. The semiconductor device manufacturing method of claim 6, wherein the processing gas includes at least one of the hydrogen gas, the nitrogen gas, or the noble gas.

8. The semiconductor device manufacturing method of claim 1, wherein the sealing film is a silicon oxide film or a silicon nitride film.

9. The semiconductor device manufacturing method of claim 1, wherein in c), the processing gas is turned into the plasma by microwaves.

10. The semiconductor device manufacturing method of claim 1, wherein the sacrificial material is a thermally decomposable organic material, and
wherein in c), the substrate is heated to a temperature at which the sacrificial material is thermally decomposed.

11. A semiconductor device manufacturing system, comprising:
a first processing apparatus;
a second processing apparatus;
a third processing apparatus; and
a controller configured to control the first processing apparatus, the second processing apparatus, and the third processing apparatus,
wherein the controller executes:
a) by using the first processing apparatus, embedding a sacrificial material in a recess formed in a substrate;
b) by using the second processing apparatus, covering the recess in which the sacrificial material is embedded with a sealing film; and
c) by using the third processing apparatus, decomposing the sacrificial material in the recess by turning a processing gas into plasma outside the recess and supplying active species contained in the plasma to the sacrificial material via the sealing film, and removing the sacrificial material in the recess via the sealing film.
